(19) United States
(12) Patent Application Publication
(10) Pub. No.: US 2008/0217790 A1
(43) Pub. Date: Sep. 11, 2008

(54) SEMICONDUCTOR DEVICE AND MANUFACTURING METHOD THEREOF

(75) Inventor: Eiji HASUNUMA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/035,229

(22) Filed: Feb. 21, 2008

(30) Foreign Application Priority Data
Mar. 9, 2007 (JP) 2007-060312

(51) Int. Cl. H01L 23/48; H01L 21/4763

(52) U.S. Cl. 257/774; 438/640; 257/E21.495; 257/E23.01

(57) ABSTRACT

A semiconductor device having a vertical conductive structure which includes a first inter-layer insulating film; a second inter-layer insulating film formed on the first inter-layer insulating film; a lower-layer contact plug which passes through the first inter-layer insulating film and the second inter-layer insulating film, wherein in the lower-layer contact plug, the outer diameter of the upper surface is smaller than the outer diameter at the boundary position between the first inter-layer insulating film and the second inter-layer insulating film; a third inter-layer insulating film formed on the second inter-layer insulating film; and an upper-layer contact plug which passes through the third inter-layer insulating film on the lower-layer contact plug, and is electrically connected to the lower-layer contact plug. Typically, a wiring line, which is insulated from the lower-layer contact plug and the upper-layer contact plug, is formed between the second inter-layer insulating film and the third inter-layer insulating film.

### BACKGROUND OF THE INVENTION

1. Field of the Invention

The present invention relates to a semiconductor device and a manufacturing method thereof, and in particular, relates to a semiconductor device having a vertical conductive structure which contributes to downsizing of the semiconductor device, and manufacturing method thereof.

Priority is claimed on Japanese Patent Application No. 2007-060312, filed Mar. 9, 2007, the contents of which are incorporated herein by reference.

2. Description of the Related Art

FIG. 6 is a diagram for explaining the sectional structure of a conventional semiconductor device, and is a general sectional view showing the vertical conductive structure of the semiconductor device. In FIG. 6, reference numeral 10 indicates a lower-layer contact plug made of a conductive film, and reference numeral 11 indicates a lower inter-layer insulating film formed on a semiconductor substrate (not shown). In addition, reference numeral 2 indicates an upper-layer contact plug made of a conductive film, reference numeral 21 indicates a wiring line made of a conductive film, and reference numeral 12 indicates an upper inter-layer insulating film.

As shown in FIG. 6, the upper-layer contact plug 2 passes through the upper inter-layer insulating film 12 to the lower-layer contact plug 10, and is electrically connected to the lower-layer contact plug 10. In addition, the lower-layer contact plug 10 and the upper-layer contact plug 2 are insulated from the wiring line 21 by means of the lower inter-layer insulating film 11 and the upper inter-layer insulating film 12.

The vertical conductive structure shown in FIG. 6 can be manufactured by the following processes. First, the lower inter-layer insulating film 11 is formed on a semiconductor substrate, and is dry-etched using a photoresist, so as to provide a contact hole 10a (see FIG. 7). In the next step, a conductive film is formed on the lower inter-layer insulating film 11 and in the contact hole 10a by means of CVD (chemical vapor deposition), and then the conductive film on the lower inter-layer insulating film 11 is removed by means of dry etch back or CMP (chemical-mechanical polishing), thereby forming the lower-layer contact plug 10, as shown in FIG. 7.

In the next step, a conductive film is formed on the lower inter-layer insulating film 11 by means of sputtering, and is then dry-etched using a photoresist, thereby forming the wiring line 21 (see FIG. 8).

Next, the upper inter-layer insulating film 12 shown in FIG. 6 is formed on the lower-layer contact plug 10, the lower inter-layer insulating film 11, and the wiring line 21, and is then dry-etched using a photoresist, thereby forming a through-hole 2a (see FIG. 6) on the lower-layer contact plug 10. After that, a conductive film is formed on the upper inter-layer insulating film 12 and in the through-hole 2a by means of CVD, and the conductive film on the upper inter-layer insulating film 12 is removed by means of dry etch back or CMP, thereby forming the upper-layer contact plug 2, as shown in FIG. 6.

In the vertical conductive structure shown in FIG. 6, in order to reliably connect the lower-layer contact plug 10 and the upper-layer contact plug 2, it is necessary to prevent the upper-layer contact plug 2 from being offset from the lower-layer contact plug 10, that is, being formed on an area other than the top surface of the lower-layer contact plug 10. Therefore, as shown in FIG. 6, the outer diameter of the upper surface of the lower-layer contact plug 10 is set larger than that of the bottom surface of the upper-layer contact plug 2 by an offset margin 10b, so as to increase the area where the upper-layer contact plug 2 can contact the upper surface of the lower-layer contact plug 10.

However, in the vertical conductive structure of FIG. 6, when the offset margin 10b is of considerable size, the size of the vertical conductive structure itself is considerably increased. If only the offset margin 10b is increased without increasing the size of the vertical conductive structure, the distance between the wiring line 21 and the lower-layer contact plug 10 is decreased, so that a sufficient amount of short margin 11a for preventing a short circuit between the wiring line 21 and the lower-layer contact plug 10 cannot be provided. Therefore, in the vertical conductive structure of FIG. 6, it is difficult to provide sufficient amounts of the short margin 11a and the offset margin 10b without increasing the size of the vertical conductive structure.

On the other hand, recently, further fine processing and downsizing of semiconductor devices have been developed. As a technique for reducing the size of the semiconductor devices, a method of manufacturing a semiconductor device has been proposed, which includes the steps of (i) forming a stack body on a base material by repeatedly performing a process of forming an insulating resin film and a process of forming a via-plug on the insulating resin film; (ii) removing the base material from the stack body; and (iii) arranging devices on a surface of the stack body, from which the base material was removed (see, for example, Japanese Unexamined Patent Application, First Publication No. 2005-236035).

In addition, a method of forming contact points of a semiconductor device is also known, by which a misalign margin between each contact plug and a conductive film pattern thereon can be increased by reducing the opening size of the contact hole (see, for example, Japanese Unexamined Patent Application, First Publication No. 2000-40674).

Additionally, in a known technique relating to semiconductor devices, a barrier metal film is reliably formed on a wiring line which includes a contact, so as to improve reliability of the wiring line which includes the contact (see, for example, Japanese Unexamined Patent Application, First Publication No. 2004-342702).

However, even when employing the above-described conventional techniques, it is still difficult to provide sufficient amounts of: (i) the short margin for preventing a short circuit between a wiring line and a lower-layer contact plug close thereto, and (ii) the offset margin for reliably contacting the lower-layer contact plug and a corresponding upper-layer contact plug, without increasing the size of the vertical conductive structure.

### SUMMARY OF THE INVENTION

In light of the above circumstances, an object of the present invention is to provide a vertical conductive structure for providing sufficient amounts of the offset margin and the short margin without increasing the size of the vertical conductive structure. The present invention also has an object to provide a method of manufacturing a semiconductor device, by which sufficient amounts of the offset margin and the short margin are provided without increasing the size of the vertical conductive structure, so that a lower-layer contact plug and a corresponding upper-layer contact plug can be reliably connected to each other, and a short circuit between the lower-layer contact plug and a wiring line close thereto can be reliably prevented.

Therefore, the present invention provides a semiconductor device having a vertical conductive structure which includes:

a first inter-layer insulating film;

a second inter-layer insulating film formed on the first inter-layer insulating film;

a lower-layer contact plug which passes through the first inter-layer insulating film and the second inter-layer insulating film, wherein in the lower-layer contact plug, the outer diameter of the upper surface is smaller than the outer diameter at the boundary position between the first inter-layer insulating film and the second inter-layer insulating film;

a third inter-layer insulating film formed on the second inter-layer insulating film; and

an upper-layer contact plug which passes through the third inter-layer insulating film on the lower-layer contact plug, and is electrically connected to the lower-layer contact plug.

In a typical example:

the lower-layer contact plug includes an upper plug which passes through the first inter-layer insulating film, and a lower plug which passes through the second inter-layer insulating film;

the upper plug and the lower plug each have a tapered form whose diameter gradually increases from the lower end to the upper end thereof; and

at the boundary position in the lower-layer contact plug, a step part is formed where the upper surface of the lower plug contacts the second inter-layer insulating film.

In this case, it is possible that:

a part of the bottom surface of the upper-layer contact plug protrudes from the upper surface of the lower-layer contact plug in plan view;

the upper-layer contact plug has an extra part which is positioned lower than the upper surface of the lower-layer contact plug; and

the extra part is electrically connected to a side face of the lower-layer contact plug, the side face being arranged from the upper surface of the lower-layer contact plug to the boundary position.

In another typical example, a wiring line, which is insulated from the lower-layer contact plug and the upper-layer contact plug, is formed between the second inter-layer insulating film and the third inter-layer insulating film.

Preferably, a dummy wiring line is formed between the lower-layer contact plug and the upper-layer contact plug.

The present invention also provides a method of manufacturing the semiconductor device having the vertical conductive structure as described above, the method comprising the steps of:

forming the first inter-layer insulating film;

forming the second inter-layer insulating film on the first inter-layer insulating film;

forming a lower-layer contact hole by using an etching method in which the first inter-layer insulating film has an etching rate higher than that of the second inter-layer insulating film, wherein the lower-layer contact hole passes through the first inter-layer insulating film and the second inter-layer insulating film, and in the lower-layer contact hole, the inner diameter of the upper edge is smaller than the inner diameter at the boundary position between the first inter-layer insulating film and the second inter-layer insulating film;

forming a conductive film in the lower-layer contact hole so as to form the lower-layer contact plug;

forming the third inter-layer insulating film on the second inter-layer insulating film; and

forming an upper-layer contact plug, which is electrically connected to the lower-layer contact plug, by forming an upper-layer contact hole which passes through the third inter-layer insulating film on the lower-layer contact plug, and forming a conductive film in the upper-layer contact hole.

In a typical example, the lower-layer contact hole includes:

an upper hole which passes through the first inter-layer insulating film, and has a tapered form whose diameter gradually increases from the lower end to the upper end thereof;

a lower hole which passes through the second inter-layer insulating film, and has a tapered form whose diameter gradually increases from the lower end to the upper end thereof; and

a step part formed at the boundary position in the lower-layer contact hole, wherein the upper surface of the lower hole contacts the second inter-layer insulating film at the step part.

The method may further comprises the step of forming a wiring line, which is insulated from the lower-layer contact plug and the upper-layer contact plug, on the second inter-layer insulating film before the step of forming the third inter-layer insulating film is performed.

The method may further comprises the step of forming a dummy wiring line on the lower-layer contact plug so as to be connected thereto before the step of forming the third inter-layer insulating film is performed.

The semiconductor device of the present invention has the lower-layer contact plug which passes through the first inter-layer insulating film and the second inter-layer insulating film, wherein the outer diameter of the upper surface of the lower-layer contact plug is smaller than the outer diameter thereof at the boundary position between the first inter-layer insulating film and the second inter-layer insulating film. Therefore, even when a part of the bottom surface of the upper-layer contact plug protrudes from the upper surface of the lower-layer contact plug in plan view, the protruding part of the upper-layer contact plug can be electrically connected to the lower-layer contact plug in a range from the upper surface of the lower-layer contact plug to the boundary position. Accordingly, in plan view, the area of the lower-layer contact plug at the boundary position can be regarded as the connectable area between the bottom surface of the upper-layer contact plug and the lower-layer contact plug.

Therefore, in accordance with the semiconductor device of the present invention, it is possible to reliably connect the lower-layer contact plug and the upper-layer contact plug to each other. In addition, the outer diameter of the upper surface in the lower-layer contact plug can be small regardless of the provision of the offset margin. Therefore, even when a wiring line, which is insulated from the lower-layer contact plug and the upper-layer contact plug, is formed between the second inter-layer insulating film and the third inter-layer insulating film, a sufficient distance can be provided between the wiring line and the lower-layer contact plug, thereby providing a sufficient short margin for preventing a short circuit between the wiring line and the lower-layer contact plug.

On the other hand, the manufacturing method (of the semiconductor device) of the present invention includes the steps of: forming a lower-layer contact hole by using an etching method in which the first inter-layer insulating film has an etching rate higher than that of the second inter-layer insulating film, wherein the lower-layer contact hole passes through the first inter-layer insulating film and the second inter-layer insulating film, and in the lower-layer contact hole, the inner diameter of the upper edge is smaller than the inner diameter at the boundary position between the first inter-layer insulating film and the second inter-layer insulating film; and forming a conductive film in the lower-layer contact hole so as to form the lower-layer contact plug. Therefore, it is possible to manufacture the semiconductor device of the present invention, in which the outer diameter of the upper surface of the lower-layer contact plug is smaller than the outer diameter thereof at the boundary position between the first inter-layer insulating film and the second inter-layer insulating film.

### BRIEF DESCRIPTION OF THE DRAWINGS

FIG. 1 is a diagram showing the sectional structure of a semiconductor device as a first embodiment of the present invention, and is a general sectional view showing the vertical conductive structure of the semiconductor device.

FIG. 2 is a sectional view used for explaining the method of manufacturing the semiconductor device in FIG. 1.

FIG. 3 is a diagram showing the sectional structure of a semiconductor device as a second embodiment of the present invention, and is a general sectional view showing another vertical conductive structure applicable to semiconductor devices.

FIG. 4 is a sectional view used for explaining the method of manufacturing the semiconductor device in FIG. 3.

FIG. 5 is a diagram showing the sectional structure of a semiconductor device as a third embodiment of the present invention, and is a general sectional view of the semiconductor device which has the vertical conductive structure as shown in FIG. 1.

FIG. 6 is a diagram for explaining the sectional structure of a conventional semiconductor device, and is a general sectional view showing the vertical conductive structure of the semiconductor device.

FIG. 7 is a sectional view used for explaining the method of manufacturing the semiconductor device in FIG. 6.

FIG. 8 is also a sectional view used for explaining the method of manufacturing the semiconductor device in FIG. 6.

### DETAILED DESCRIPTION OF THE INVENTION

Hereinafter, embodiments of the present invention will be described with reference to the appended figures.

### First Embodiment

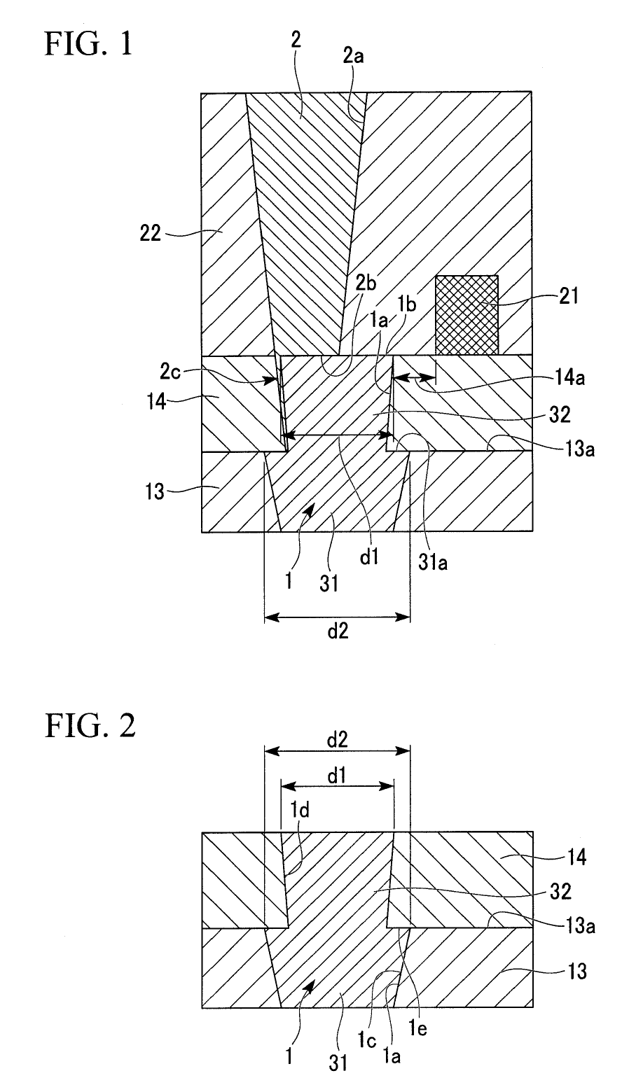

A semiconductor device and a manufacturing method thereof, as a first embodiment of the present invention, will be explained with reference to FIGS. 1 and 2.

FIG. 1 is a diagram showing the sectional structure of the semiconductor device, and is a general sectional view showing the vertical conductive structure of the semiconductor device.

In FIG. 1, reference numeral 1 indicates a lower-layer contact plug made of a conductive film (e.g., W/TiN/Ti), reference numeral 13 indicates a first inter-layer insulating film formed on a silicon substrate (not shown), and reference numeral 14 indicates a second inter-layer insulating film formed on the first inter-layer insulating film 13.

The lower-layer contact plug 1 passes through the first inter-layer insulating film 13 and the second inter-layer insulating film 14. As shown in FIG. 1, the upper surface 1b of the lower-layer contact plug 1 has an outer diameter d1 which is smaller than the outer diameter d2 of the area (of the lower-layer contact plug 1) along the boundary position 13a between the first inter-layer insulating film 13 and the second inter-layer insulating film 14. In addition, the lower-layer contact plug 1 consists of a lower plug 31 arranged through the first inter-layer insulating film 13 and an upper plug 32 arranged through the second inter-layer insulating film 14. The lower plug 31 and the upper plug 32 each have a tapered form whose diameter gradually increases from the lower end to the upper end. Additionally, at the boundary position 13a between the first inter-layer insulating film 13 and the second inter-layer insulating film 14, a step part 31a is formed where the upper surface of the lower plug 31 contacts the second inter-layer insulating film.

In the present embodiment, the first inter-layer insulating film 13 is made of a BPSG (boro-phospho silicate glass) film which includes B or P impurities and has a relatively high wet etching rate with respect to an etchant made using an acid such as hydrofluoric acid.

The second inter-layer insulating film 14 is made of a TEOS (tetra ethyl ortho silicate)-NSG (non-doped silicate glass) film or a plasma oxide film such as a TEOS plasma oxide film or an SiH₄ (silane) plasma oxide film, made by plasma CVD, where either film has a relatively low wet etching rate with respect to an etchant made using an acid such as hydrofluoric acid.

When the first inter-layer insulating film 13 and the second inter-layer insulating film 14 is wet-etched using an etchant made using an acid such as hydrofluoric acid, the second inter-layer insulating film is made of a material by which the etching rate of the first inter-layer insulating film 13 is higher than that of the second inter-layer insulating film 14. Preferably, the etching rate of the first inter-layer insulating film 13 is approximately five times higher than that of the second inter-layer insulating film 14. For example, when performing wet etching using rare hydrofluoric acid, it is preferable to form the first inter-layer insulating film 13 by using a BPSG film, and form the second inter-layer insulating film 14 by using a TEOS plasma oxide film.

The materials for forming the first inter-layer insulating film 13 and the second inter-layer insulating film 14 are not limited to those described above. The first inter-layer insulating film 13 may be an insulating film having a higher impurity concentration in comparison with the second inter-layer insulating film 14. More specifically, the first inter-layer insulating film 13 may be a BPSG film including impurities having a relatively high impurity concentration, while the second inter-layer insulating film 14 may be a BPSG film including impurities having a relatively low impurity concentration.

In addition, in order to etch the first inter-layer insulating film 13 and the second inter-layer insulating film 14 so as to form the lower-layer contact plug 1, they are formed using different insulating materials so that the etching rate of the first inter-layer insulating film 13 is higher than that of the second inter-layer insulating film 14. More specifically, the first inter-layer insulating film 13 and the second inter-layer insulating film 14 may be made of two different insulating materials having different etching rates with respect to isotropic dry etching such as CDE (chemical dry etching), which uses a carbon-fluoride gas such as CF₄, a mixed gas of a carbon-fluoride gas such as CF₄ and O₂, or the like. Preferably, the dry etching rate of the first inter-layer insulating film 13 is approximately five times higher than that of the second inter-layer insulating film 14.

As an example of the combination of the first inter-layer insulating film 13 and the second inter-layer insulating film 14 which are made of two different insulating materials having different etching rates with respect to the isotropic dry etching, the first inter-layer insulating film 13 may be an insulating film including impurities, such as a PSG film (including P) or an FSG film (including F), and the second inter-layer insulating film 14 may be an NSG film such as a TEOS oxide film or an SiH₄ oxide film.

In addition, when performing CDE using a mixed gas of CF₄ and O₂, it is preferable to form the first inter-layer insulating film 13 using a BRSG film, and to form the second inter-layer insulating film 14 using a TEOS plasma oxide film.

As shown in FIG. 1, a wiring line 21 made of a conductive film (e.g., W/WN) is formed on the second inter-layer insulating film 14. The side and top faces of the wiring line 21 is covered with a third inter-layer insulating film 22, which is also formed on the second inter-layer insulating film 14 and is made of an insulating material such as a silicon oxide film. The wiring line 21 is arranged between the second inter-layer insulating film 14 and the third inter-layer insulating film 22, and is insulated from the lower-layer contact plug 1 and the upper-layer contact plug 2 which is made of a conductive film (e.g., W/TiN).

Generally, the upper-layer contact plug 2 is formed on the lower-layer contact plug 1 so as to be electrically connected thereto, and passes through the third inter-layer insulating film 22. The upper-layer contact plug 2 has a tapered form whose diameter gradually increases from the lower end to the upper end. As shown in FIG. 1, in the present embodiment, the central axis of the lower-layer contact plug 1 is offset from the central axis of the upper-layer contact plug 2 in plan view. Therefore, a part of the bottom surface 2b of the upper-layer contact plug 2 protrudes from the upper surface 1b of the lower-layer contact plug 1 in plan view, that is, the upper-layer contact plug 2 partially protrudes from the upper surface 1b of the lower-layer contact plug 1. Accordingly, the upper-layer contact plug 2 has an extra part 2c which is positioned lower than the upper surface 1b of the lower-layer contact plug 1 and protrudes from the upper surface 1b. The extra part 2c is electrically connected to the side face of the lower-layer contact plug 1, arranged from the upper surface 1b to the boundary position 13a, and also to the step part 31a of the lower-layer contact plug 1.

In order to manufacture the semiconductor device shown in FIG. 1, first, the first inter-layer insulating film 13 is formed on a silicon substrate (not shown), and the second inter-layer insulating film 14 is further formed on the first inter-layer insulating film 13.

In the next step, a contact hole (not shown) is formed by means of isotropic dry etching such as RIE (reactive ion etching) by using a photoresist, where the contact hole passes through the first inter-layer insulating film 13 and the second inter-layer insulating film 14, has no step part on the wall surface thereof, and has a tapered form whose diameter gradually increases from the lower end to the upper end.

Next, wet etching using an etchant such as hydrofluoric acid is performed. For example, when the first inter-layer insulating film 13 is made of a BGSG film, the second inter-layer insulating film 14 is made of a TEOS plasma oxide film, and the etchant is a rare hydrofluoric acid of “500 (H₂O):1 (HF)”, then the wet etching is executed for approximately three minutes. Through the wet etching, in accordance with a difference in the wet etching rate between the first inter-layer insulating film 13 and the second inter-layer insulating film 14, a lower-layer contact hole 1a is provided in a manner such that the inner diameter (corresponding to the outer diameter d1 of the upper surface 1b in the lower-layer contact plug 1) of the upper edge of the lower-layer contact hole 1a is smaller than the inner diameter (corresponding to the outer diameter d2 of the lower-layer contact plug 1 at the boundary position 13a) of the area at the boundary position 13a between the first inter-layer insulating film 13 and the second inter-layer insulating film 14 (see FIGS. 1 and 2).

The lower-layer contact hole 1a as formed above includes (i) a lower hole 1c which passes through the first inter-layer insulating film 13 and has a tapered form whose diameter gradually increases from the lower end to the upper end, (ii) an upper hole 1d which passes through the second inter-layer insulating film 14 and has a tapered form whose diameter gradually increases from the lower end to the upper end, and (iii) a step part 1e formed at the boundary position 13a between the first inter-layer insulating film 13 and the second inter-layer insulating film 14, where the top surface of the lower hole 1c contacts the second inter-layer insulating film 14 at the step part 1e.

In the above-described method of forming the lower-layer contact hole 1a, wet etching using an acid such as hydrofluoric acid is performed. However, instead of wet etching, dry etching such as CDE may be performed. In this case, for example, the first inter-layer insulating film 13 is made by a BRSG film, the second inter-layer insulating film is made by a TEOS plasma oxide film, and CDE using a mixed gas of CF₄ and O₂ is performed. Also in this case, in accordance with a difference in the dry etching rate between the first inter-layer insulating film 13 and the second inter-layer insulating film 14, the lower-layer contact hole 1a having a form similar to that obtained by the wet etching is formed.

In the next step, on the second inter-layer insulating film 14 and in the lower-layer contact hole 1a, a conductive film (e.g., W/TiN/Ti) is formed by means of CVD, and then the conductive film on the second inter-layer insulating film 14 is removed by means of dry etch back or CMP, thereby forming the lower-layer contact plug 1 as shown in FIG. 2.

The lower-layer contact plug 1, as formed above, has a form transferred from the lower-layer contact hole 1a. That is, as shown in FIG. 2, the lower-layer contact plug 1 passes through the first inter-layer insulating film 13 and the second inter-layer insulating film 14, and has the upper surface 1b whose outer diameter d1 is smaller than the outer diameter d2 at the boundary position 13a between the first inter-layer insulating film 13 and the second inter-layer insulating film 14.

In the next step, on the second inter-layer insulating film 14, a conductive film (e.g., W/WN) is formed by means of sputtering, and it is then dry-etched using a photoresist, so as to form the wiring line 21 shown in FIG. 1.

Next, the third inter-layer insulating film 22 shown in FIG. 1 is formed on the lower-layer contact plug 1, the second inter-layer insulating film 14, and the wiring line 21. The third inter-layer insulating film 22 is then dry or wet-etched using a photoresist, so as to form the through-hole 2a (i.e., upper-layer contact hole) which passes through the third inter-layer insulating film 22 on the lower-layer contact plug 1 (see FIG. 1). After that, a conductive film (e.g., W/TiN) is formed on the third inter-layer insulating film 22 and in the through-hole 2a by means of CVD, and the conductive film on the third inter-layer insulating film 22 is then removed by means of dry etch back or CMP, thereby forming the upper-layer contact plug 2 (see FIG. 1) which is electrically connected to the lower-layer contact plug 1.

The semiconductor device of the present embodiment has a vertical conductive structure including the lower-layer contact plug 1, which passes through the first inter-layer insulating film 13 and the second inter-layer insulating film 14, and has the upper surface 1b whose outer diameter d1 is smaller than the outer diameter d2 at the boundary position 1 3a between the first inter-layer insulating film 13 and the second inter-layer insulating film 14. Therefore, even when a part of the bottom surface 2b of the upper-layer contact plug 2 protrudes from the upper surface 1b of the lower-layer contact plug 1 in plan view, the extra part 2c of the upper-layer contact plug 2 can be electrically connected to the side face of the lower-layer contact plug 1, arranged from the upper surface 1b to the boundary position 13a.

Accordingly, the area (corresponding to the outer diameter d2) of the lower-layer contact plug 1 at the boundary position 13a in plan view can be regarded as an area to which the bottom surface 2b of the upper-layer contact plug 2 can be connected. Therefore, in accordance with the semiconductor device of the present embodiment, the lower-layer contact plug 1 and the upper-layer contact plug 2 can be reliably connected to each other.

Additionally, in the semiconductor device of the present embodiment, the connectable area between the bottom surface 2b of the upper-layer contact plug 2 and the lower-layer contact plug 1 is not determined by the outer diameter d1 of the upper surface 1b in the lower-layer contact plug 1. Therefore, the outer diameter d1 of the upper surface 1b in the lower-layer contact plug 1 can be small regardless of the above-described provision of the offset margin. Therefore, in accordance with the semiconductor device of the present embodiment, even when the wiring line 21, which is insulated from the lower-layer contact plug 1 and the upper-layer contact plug 2, is formed between the second inter-layer insulating film 14 and the third inter-layer insulating film 22, a sufficient distance can be provided between the wiring line 21 and the lower-layer contact plug 1, thereby providing a sufficient short margin 14a for preventing a short circuit between the wiring line 21 and the lower-layer contact plug 1.

Also in the semiconductor device of the present embodiment, the lower-layer contact plug 1 consists of the lower plug 31 arranged through the first inter-layer insulating film 13 and the upper plug 32 arranged through the second inter-layer insulating film 14, wherein the lower plug 31 and the upper plug 32 each have a tapered form whose diameter gradually increases from the lower end to the upper end, and the step part 31a is formed at the boundary position 13a. Therefore, the extra part 2c of the upper-layer contact plug 2 can be electrically connected to the side face of the lower-layer contact plug 1, arranged from the upper surface 1b to the boundary position 13a, and to the step part 31a of the lower-layer contact plug 1. In addition, when performing etching for forming the through-hole 2a which is used for forming the upper-layer contact plug 2, the step part 31 a can function as an etching stopper, so that the upper-layer contact plug 2 does not protrude the step part 31a of the lower-layer contact plug 1. Therefore, it is possible to more reliably connect the upper-layer contact plug 2 and the lower-layer contact plug 1 to each other.

Also in the semiconductor device of the present embodiment, when the first inter-layer insulating film 13 is made by a BPSG film, and the second inter-layer insulating film is made by a TEOC-NSG film or a plasma oxide film including no impurities, such as a TEOS plasma oxide film or an SiH₄ plasma oxide film, the lower contact hole 1a having a form corresponding to the lower-layer contact plug 1 (see FIG. 1) can be easily formed by using a difference in the etching rate between the first inter-layer insulating film 13 and the second inter-layer insulating film 14, with respect to wet etching using an acid (e.g., hydrofluoric acid) as the etchant. Therefore, the semiconductor device of the present embodiment can be easily manufactured.

The method of manufacturing the semiconductor device in the present embodiment includes (i) a step of forming a lower contact hole 1a by using an etching method in which the etching rate of the first inter-layer insulating film 13 is higher than that of the second inter-layer insulating film 14, wherein the lower contact hole 1a passes through the first inter-layer insulating film 13 and the second inter-layer insulating film 14, and in the lower contact hole 1a, the inner diameter (corresponding to the outer diameter d1 of the upper surface 1b in the lower-layer contact plug 1) of the upper edge is smaller than the inner diameter (corresponding to the outer diameter d2 of the lower-layer contact plug 1) at the boundary position 13a between the first inter-layer insulating film 13 and the second inter-layer insulating film 14, and (ii) a step of forming the lower-layer contact plug 1 by forming a conductive film in the lower contact hole 1a. Therefore, it is possible to manufacture a semiconductor device having the lower-layer contact plug 1 in which the outer diameter d1 of the upper surface 1b is smaller than the outer diameter d2 at the boundary position 13a.

### Second Embodiment

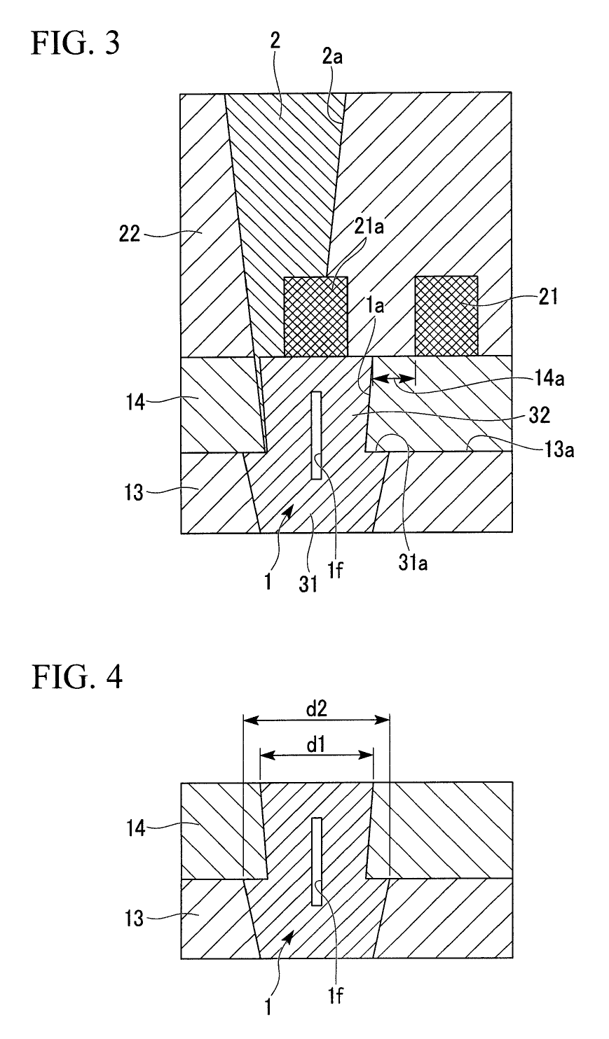

Below, a semiconductor device and a manufacturing method thereof as a second embodiment of the present invention will be explained with reference to FIGS. 3 to 4.

FIG. 3 is a diagram showing the sectional structure of the semiconductor device, and is a general sectional view showing another vertical conductive structure applicable to semiconductor devices. In FIG. 3, parts identical to those in FIG. 1 are given identical reference numerals, and explanations thereof are omitted. In comparison with the semiconductor device of the first embodiment (see FIG. 1), the semiconductor device of the present embodiment has distinctive features such that a cavity 1f (or seam), which is a space provided at a center of the lower-layer contact plug 1, is formed, and a dummy wiring line 21a is formed between the lower-layer contact plug 1 and the upper-layer contact plug 2.

The dummy wiring line 21a shown in FIG. 3 is made by a conductive film (e.g., W/WN), and preferably, by the same material for forming the wiring line 21, so as to simultaneously form both wiring lines. It is possible for the dummy wiring line 21a not to contribute to any circuit operation of the semiconductor device, however, it may contribute to the circuit operation.

The semiconductor device shown in FIG. 3 may be manufactured by the following method. First, similar to the above-described method of manufacturing the semiconductor device of FIG. 1, each step for forming the lower-layer contact hole 1a is performed. After that, on the second inter-layer insulating film 14 and in the lower-layer contact hole 1a, a conductive film (e.g., W/TiN/Ti) is formed by means of CVD. In this process, if the coverage of the conductive film formed in the lower-layer contact hole 1a is insufficient, the cavity 1f is produced. After that, the conductive film on the second inter-layer insulating film 14 is removed by means of dry etch back or CMP, so as to form the lower-layer contact plug 1 shown in FIG. 4.

Next, before the third inter-layer insulating film 22 is formed on the second inter-layer insulating film 14, the dummy wiring line 21a is formed on the lower-layer contact plug 1. When the dummy wiring line 21a and the wiring line 21 are formed using the same material, it is preferable to form them simultaneously. The steps performed after forming the dummy wiring line 21a and the wiring line 21 are performed similar to the method of manufacturing the semiconductor device of FIG. 1.

In the semiconductor device of the present embodiment, the dummy wiring line 21a is provided between the lower-layer contact plug 1 and the upper-layer contact plug 2, thereby providing the following effects.

As shown in FIG. 3, when the cavity 1f is formed at a center of the lower-layer contact plug 1, then during the etching for forming the through-hole 2a which is used for forming the upper-layer contact plug 2, the etchant may reach and enter the cavity 1f, and may further reach the substrate so that the substrate may be etched. In addition, if the cavity 1f is exposed at the bottom surface of the through-hole 2a after the through-hole 2a for forming the upper-layer contact plug 2 is formed, then (i) the lower-layer contact plug 1 may be detached from the through-hole 1a, or (ii) a resist separation liquid or a polymer removal liquid, which is used after the etching of the through-hole 2a, or a pretreatment liquid, which is used in a wet processing performed before the formation of the conductive film in the through-hole 2a, may enter the cavity 1f and stay in it, which may cause an insufficient dry condition.

However, in the semiconductor device of the present embodiment, the dummy wiring line 21a is formed between the lower-layer contact plug 1 and the upper-layer contact plug 2. Therefore, even when the cavity 1f is present at a center of the lower-layer contact plug 1, it is possible to prevent the etchant from reaching the cavity if during the etching for forming the through-hole 2a which is used for forming the upper-layer contact plug 2. Accordingly, the etchant never enters the cavity 1f. In addition, after the through-hole 2a for forming the upper-layer contact plug 2 is formed, the cavity 1f is not exposed at the bottom surface of the through-hole 2a. Therefore, there is no inconvenience caused by the cavity 1f which is present at a center of the lower-layer contact plug 1.

### Third Embodiment

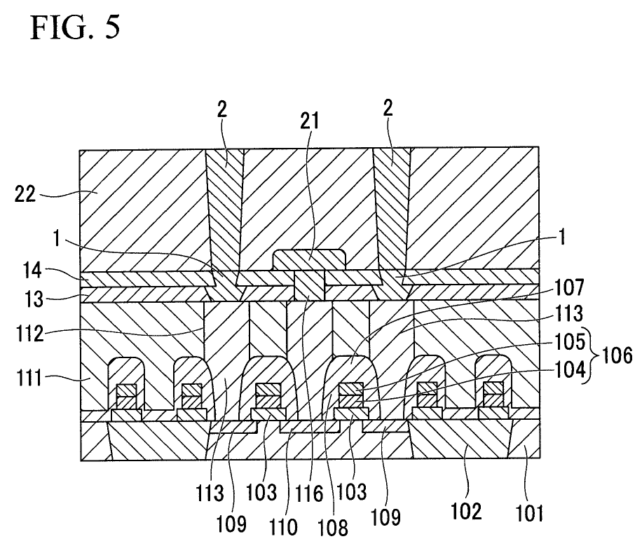

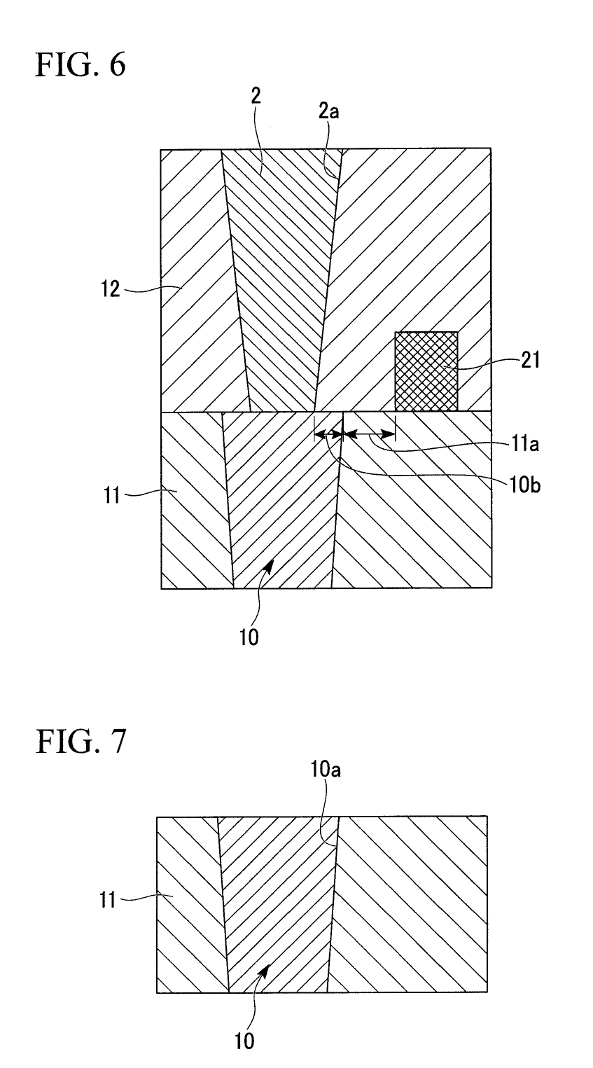

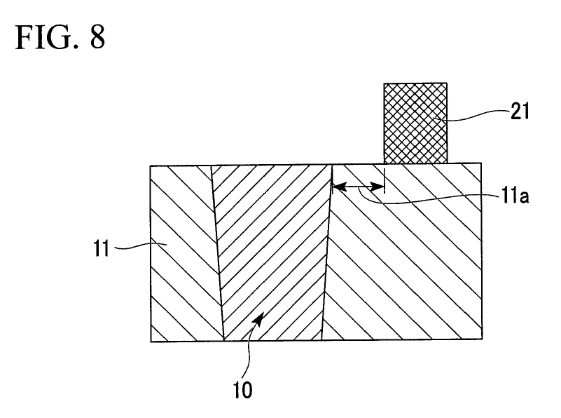

Below, a semiconductor device as a third embodiment of the present invention will be explained with reference to FIG. 5.

FIG. 5 is a diagram showing the sectional structure of the semiconductor device, and is a general sectional view showing the semiconductor device which has the vertical conductive structure as shown in FIG. 1. In FIG. 5, parts identical to those in FIG. 1 are given identical reference numerals, and explanations thereof are omitted.

In FIG. 5, reference numeral 101 indicates a semiconductor substrate made of a semiconductor (e.g., silicon) including impurities of a specific impurity rate. In the surface of the semiconductor substrate 101, an insulating separating area 102 is formed by means of STI (shallow trench isolation). The insulating separating area 102 is formed in each area other than the area where each transistor is formed, so as to isolate each transistor in an insulating condition. Each gate insulating film 103 is made of a silicon oxide film or the like. Each gate electrode 106 is formed using a multilayered film consisting of a polysilicon film 104 and a metal film 105 which is made of refractory metal (i.e., having a high melting point) such as tungsten (W) or tungsten silicide (WSi). On each gate electrode 106, an insulating film 107 made of silicon nitride (SiN) or the like is formed, and a side wall 108 made of an insulating film which may be made of silicon nitride is formed on the side wall of the gate electrode 106.

Additionally, in FIG. 5, reference numeral 110 indicates a drain, and sources 109 are formed on both side thereof. On the drain 110 and each source 109, the gate insulating film 103 is formed so as to connect them, and the gate electrode 106 is formed on the gate insulating film 103.

The semiconductor substrate 101 and the insulating films 107 are covered with an inter-layer insulating film 111, which is a multilayered film of a BRSG film and a TEOS-NSG film. In order to expose the sources 109 and the drain 110, cell contact holes 112 are provided so as to pass through the inter-layer insulating film 111. Each cell contact hole 112 is filled with a polysilicon film having a specific impurity concentration, thereby forming a cell contact plug 113.

On the inter-layer insulating film 111 and the cell contact plugs 11 3, the vertical conductive structure as shown in FIG. 1 is provided. In the present embodiment, a bit contact plug 116 made of a conductive material is formed so as to pass through the first inter-layer insulating film 13 and the second inter-layer insulating film 14. The wiring line 21 and the corresponding cell contact plug 113 are electrically connected to each other via the bit contact plug 116.

Also in the semiconductor device shown in FIG. 5, capacitors (not shown) functioning as storage parts for storing data are formed on the third inter-layer insulating film 22 and the upper-layer contact plug 2, thereby forming a DRAM (dynamic random access memory) structure.

As the semiconductor device of the present embodiment has the vertical conductive structure as shown in FIG. 1, the lower-layer contact plug 1 and the upper-layer contact plug 2 can be reliably connected to each other. In addition, a sufficient distance can be provided between the wiring line 21 and each relevant lower-layer contact plug 1, thereby providing a sufficient short margin for preventing a short circuit between the wiring line 21 and the lower-layer contact plug 1.

While preferred embodiments of the invention have been described and illustrated above, it should be understood that these are exemplary embodiments of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A semiconductor device having a vertical conductive structure which includes:
a first inter-layer insulating film;
a second inter-layer insulating film formed on the first inter-layer insulating film;
a lower-layer contact plug which passes through the first inter-layer insulating film and the second inter-layer insulating film, wherein in the lower-layer contact plug, the outer diameter of the upper surface is smaller than the outer diameter at the boundary position between the first inter-layer insulating film and the second inter-layer insulating film;
a third inter-layer insulating film formed on the second inter-layer insulating film; and
an upper-layer contact plug which passes through the third inter-layer insulating film on the lower-layer contact plug, and is electrically connected to the lower-layer contact plug.

2. The semiconductor device in accordance with claim 1, wherein:
the lower-layer contact plug includes an upper plug which passes through the first inter-layer insulating film, and a lower plug which passes through the second inter-layer insulating film;
the upper plug and the lower plug each have a tapered form whose diameter gradually increases from the lower end to the upper end thereof; and
at the boundary position in the lower-layer contact plug, a step part is formed where the upper surface of the lower plug contacts the second inter-layer insulating film.

3. The semiconductor device in accordance with claim 2, wherein:
a part of the bottom surface of the upper-layer contact plug protrudes from the upper surface of the lower-layer contact plug in plan view;
the upper-layer contact plug has an extra part which is positioned lower than the upper surface of the lower-layer contact plug; and
the extra part is electrically connected to a side face of the lower-layer contact plug, the side face being arranged from the upper surface of the lower-layer contact plug to the boundary position.

4. The semiconductor device in accordance with claim 1, wherein:
a wiring line, which is insulated from the lower-layer contact plug and the upper-layer contact plug, is formed between the second inter-layer insulating film and the third inter-layer insulating film.

5. The semiconductor device in accordance with claim 1, wherein:
a dummy wiring line is formed between the lower-layer contact plug and the upper-layer contact plug.

6. A method of manufacturing the semiconductor device having the vertical conductive structure in accordance with claim 1, the method comprising the steps of:
forming the first inter-layer insulating film;
forming the second inter-layer insulating film on the first inter-layer insulating film;
forming a lower-layer contact hole by using an etching method in which the first inter-layer insulating film has an etching rate higher than that of the second inter-layer insulating film, wherein the lower-layer contact hole passes through the first inter-layer insulating film and the second inter-layer insulating film, and in the lower-layer contact hole, the inner diameter of the upper edge is smaller than the inner diameter at the boundary position between the first inter-layer insulating film and the second inter-layer insulating film;
forming a conductive film in the lower-layer contact hole so as to form the lower-layer contact plug;
forming the third inter-layer insulating film on the second inter-layer insulating film; and
forming an upper-layer contact plug, which is electrically connected to the lower-layer contact plug, by forming an upper-layer contact hole which passes through the third inter-layer insulating film on the lower-layer contact plug, and forming a conductive film in the upper-layer contact hole.

7. The method in accordance with claim 6, wherein the lower-layer contact hole includes:
an upper hole which passes through the first inter-layer insulating film, and has a tapered form whose diameter gradually increases from the lower end to the upper end thereof;
a lower hole which passes through the second inter-layer insulating film, and has a tapered form whose diameter gradually increases from the lower end to the upper end thereof; and
a step part formed at the boundary position in the lower-layer contact hole, wherein the upper surface of the lower hole contacts the second inter-layer insulating film at the step part.

8. The method in accordance with claim 6, further comprising the step of:
forming a wiring line, which is insulated from the lower-layer contact plug and the upper-layer contact plug, on the second inter-layer insulating film before the step of forming the third inter-layer insulating film is performed.

9. The method in accordance with claim 6, further comprising the step of:
forming a dummy wiring line on the lower-layer contact plug so as to be connected thereto before the step of forming the third inter-layer insulating film is performed.
